(19) United States
(12) Patent Application Publication
(10) Pub. No.: US 2007/0072420 A1
(43) Pub. Date: Mar. 29, 2007

(54) Method of forming copper interconnection using dual damascene process and semiconductor device having copper interconnection according to the same

(75) Inventor: Eun Jong Shin, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/527,979

(22) Filed: Sep. 26, 2006

(30) Foreign Application Priority Data
Sep. 28, 2005 (KR) 10-2005-0090339

(51) Int. Cl. H01L 21/44

(52) U.S. Cl. 438/687

(57) ABSTRACT

Disclosed is a method of forming a copper interconnection using a dual damascene process, in which an etch profile anomaly and the trench depth variation caused by the trench etching process are reduced or prevented, so that the copper interconnection is obtained substantially without voids or interconnection defects. The method includes the steps of depositing a first dielectric layer, forming an etch stop layer having an etching selectivity with respect to the first dielectric layer, and depositing a second dielectric layer thereon. Since the via holes and the trench are simultaneously formed through the etching process using the etch stop layer, the trench depth may be precisely controlled, the manufacturing processes is simplified and the reliability of the semiconductor device is improved.

This application claims the benefit of Korean Application No. 10-2005-0090339, filed on Sep. 28, 2005, which is incorporated by reference herein in its entirety.

### BACKGROUND OF TIE INVENTION

1. Field of the Invention

The present invention relates to a metal interconnection technology of a semiconductor device. More specifically, the present invention relates to a method of forming a copper interconnection using a dual damascene process.

2. Background of the Related Art

As interest in the ultra deep sub-micron CMOS devices having sizes of 90 nm or less has grown, studies for using low-k dielectrics in copper interconnection processes have been actively performed. One of major issues to be solved in the copper interconnection technology using the low-k dielectric is an integration issue. That is, reliability of the semiconductor device, such as electro-migration (EM), stress-migration (SM), or time dependent dielectric breakdown (TDDB), which may occur due to the characteristics of the low-k material, has become a serious problem in the copper interconnection technology. In addition, as the dual damascene technology is applied to the copper interconnection process, various defects, such as an opening, a poor surface for contact at the bottom of a via hole, or a void of the copper interconnection, are presented. Theses defects may exert a bad influence upon the productivity and reliability of the semiconductor devices.

FIGS. 1a to 1d show a conventional technology for forming a copper interconnection using a low-k dielectric and a dual damascene process.

Referring to FIG. 1a, a capping layer 11 and an interlayer dielectric layer 12 are sequentially deposited on a top surface of a lower copper interconnection 10. For example, the capping layer 11 includes silicon nitride (SiN) or silicon carbon nitride (SiCN), and the interlayer dielectric layer 12 includes a stacked structure of undoped silicate glass (USG) formed from plasma-assisted deposition of silicon dioxide from monosilane (plasma silane, or p-SiH₄), fluorine-doped silicon glass (FSG) and plasma silane (p-SiH₄).

Referring to FIG. 1b, via holes 13 are formed through photolithography and dry etching processes. Then, protective layers 14 are formed in the via holes 13 in order to protect the via holes 13 while the trench etching process is being performed. For instance, the protective layer 14 is formed by performing an etch back process after filling the via holes 13 with novolac or a bottom anti-reflective coating which may be a kind of photoresist.

After that, as shown in FIG. 1c, a photoresist pattern 15 for forming a trench 16 is deposited on the interlayer dielectric layer 12, and then, the dry etching process is performed with respect to the interlayer dielectric layer 12, thereby forming the trench 16 in the interlayer dielectric layer 12. At this time, an etch profile anomaly may occur at an overlap region between the via hole 13 and the trench 16 due to the trench etching process, and the depth of the trench 16 may significantly vary depending on the density of the trench pattern. These problems may cause defects in the semiconductor device, such as voids in the copper interconnection, in the following processes while presenting reliability problems, such as electro-migration and stress-migration derived from copper diffusion.

After the trench etching process has been completed, as shown in FIG. 1d, the protective layers 14 (see, FIG. 1c) are removed from the via holes 13 and the capping layer 11 remaining on the bottom of the via holes 13 is removed through the dry etching process. Then, after depositing a diffusion barrier and a copper seed layer, copper is deposited through an electrochemical plating (ECP) process. After that, a chemical mechanical polishing (CMP) process is performed with respect to a resultant structure, thereby providing a copper interconnection 17 having the dual damascene structure.

At this time, due to the etch profile anomaly and the trench depth variation derived from the trench etching process, the copper interconnection 17 may have voids 18 or interconnection defects, so that the reliability of the semiconductor device is degraded.

### SUMMARY OF THE INVENTION

It is, therefore, an object of the present invention to provide a method of forming a copper interconnection using a dual damascene process, in which the etch profile anomaly and the trench depth variation caused by the trench etching process can be reduced prevented, so that the copper interconnection can be obtained without (or with a lower incidence of) voids or interconnection defects.

Another object of the present invention is to provide a method of forming a copper interconnection using a low-k dielectric and a dual damascene process to improve the reliability of a semiconductor device.

According to a preferred embodiment of the present invention, there is provided a method comprising the steps of depositing a first dielectric layer, forming an etch stop layer having a high etching selectivity with respect to the first interlayer dielectric layer, and depositing a second dielectric layer, wherein via holes are formed simultaneously with a trench through a subsequent etching process using the (buried) etch stop layer.

According to the present invention, there is provided a method of forming a copper interconnection, the method comprising the steps of: sequentially depositing a capping layer and a first dielectric layer on a (predetermined) lower structure; depositing an etch stop layer on the first dielectric layer; etching the etch stop layer to form a via hole pattern; depositing a second dielectric layer on the etch stop layer and the first dielectric layer; forming a photoresist pattern on the second dielectric layer; etching the second dielectric layer using the photoresist pattern as a mask, thereby forming the trench, and simultaneously etching the first dielectric layer using the etch stop layer as a mask, thereby forming via holes; removing the capping layer exposed in the via holes; and depositing copper such that the via holes and the trench are filled with copper, and chemical mechanical polishing the resultant structure, thereby obtaining the copper interconnection.

It is preferable that the etch stop layer includes a material having an etching selectivity in a range of 10:1 to 100:1 with respect to the first interlayer dielectric layer. For instance, the etch stop layer may comprise silicon nitride (SiN) and may have a thickness of 500 Å-700 Å.

Preferably, a deposition thickness of the first dielectric layer corresponds to a depth of the via hole (e.g., prior to removing the exposed capping layer), and the first dielectric layer includes the same material as the second dielectric layer. For instance, the first and second dielectric layers may comprise fluorine-doped silicon glass (FSG) or carbon-doped silicon oxide (SiOC).

### BRIEF DESCRIPTION OF DRAWINGS

FIGS. 1a to 1d are sectional views illustrating a conventional method of forming a copper interconnection;

FIGS. 2a to 2d are sectional views illustrating a method of forming a copper interconnection according to the preferred embodiment of the present invention.

### DETAILED DESCRIPTION OF TIE INVENTION

Hereinafter, preferred embodiments according to the present invention will be described in detail, with reference to the following drawings.

It should be noted that the embodiments described below do not intend to limit the scope of the present invention, but intend to assist those skilled in the art to completely understand the present invention. In the following description of the present invention, some structures or manufacturing processes can be omitted in order to avoid redundancy and to clarify the subject manner of the present invention. In the same manner, some of elements can be exaggerated, omitted or simplified in the drawings and the elements may have sizes different from those shown in the drawings, in practice.

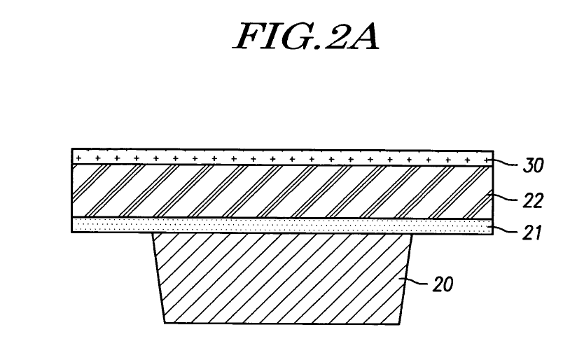

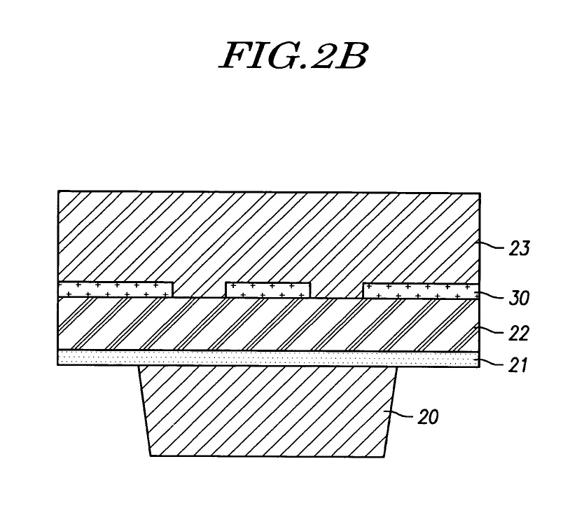

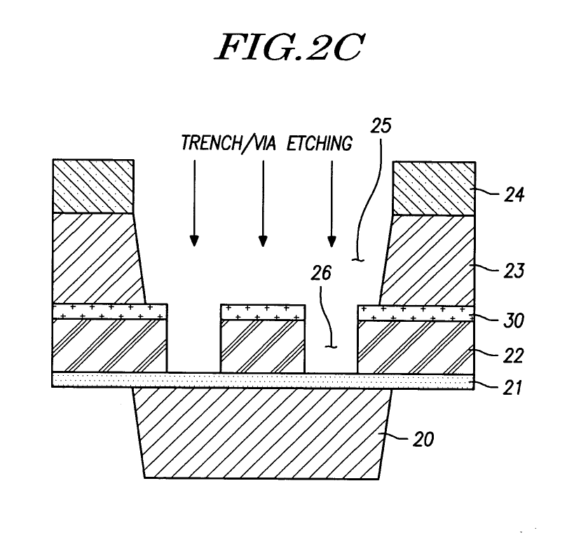

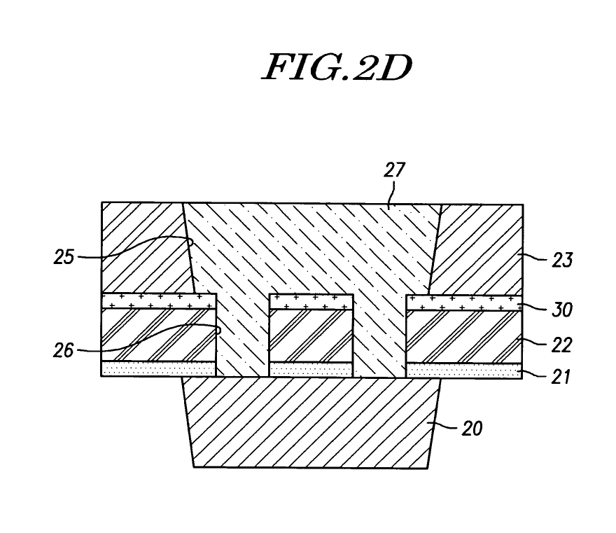

FIGS. 2a to 2d are sectional views illustrating a method of forming a copper interconnection according to a preferred embodiment of the present invention.

Referring to FIG. 2a, a capping layer 21 and a first dielectric layer (e.g., an interlayer dielectric layer) 22 are sequentially deposited on the top surface of a lower copper interconnection 20. The capping layer 21 is deposited first in order to prevent copper diffusion into the overlying first interlayer dielectric layer 22 and/or to prevent oxygen diffusion into the lower copper interconnection 20. At this time, the final deposition thickness of the first dielectric layer 22 corresponds to the depth of a via hole (e.g., 2000 Å˜2500 Å). For example, the capping layer 21 includes (comprises or consists essentially of) silicon nitride (SiN) or silicon carbon nitride (SiCN). In addition, the first dielectric layer 22 includes a low-k material, such as fluorine-doped silicon glass or carbon-doped silicon oxide. Preferably, the first dielectric layer 22 comprises a stacked structure resulting from forming a USG film (e.g., plasma silane, or p-SiH₄) on top of the capping layer 21, and then again on the fluorine-doped silicon glass or carbon-doped silicon oxide that serves as the first dielectric layer 22.

After that, an etch stop layer 30 is deposited on the top surface of the first dielectric layer 22. The etch stop layer 30 is used as an etch mask in the following via hole etching process and reduces or prevents voids from being formed in the copper interconnection. Accordingly, the etch stop layer 30 includes a material having an etching selectivity (preferably a high etching selectivity) with respect to the first dielectric layer 22. That is, the etch stop layer 30 includes a material having an etching selectivity in a range of 10:1 to 100:1 with respect to oxide (and the same or a similar selectivity with regard to FSG or carbon-doped silicon oxide [SiOC], if the first dielectric layer 22 does not include a USG, TEOS or other silicon dioxide film below the etch stop layer 30). For instance, the etch stop layer 30 typically comprises silicon nitride (SiN) and may have a thickness of 500 Å˜700 Å.

Then, as shown in FIG. 2b, after patterning a photoresist over and etching the etch stop layer 30 to form a via hole pattern, a second dielectric layer 23 (e.g., a second interlayer dielectric layer) is deposited on the patterned etch stop layer 30 and the first dielectric layer 22. Preferably, the second dielectric layer 23 includes a material identical to a material in the first dielectric layer 22, although the second dielectric layer 23 may have the same or a different stacked structure as the first dielectric layer 22. Because the etch stop layer 30 is between the first and second dielectric layers 22 and 23, it may be considered to be a “buried” etch stop layer.

After that, as shown in FIG. 2c, a photoresist pattern 24 for forming a trench 25 is deposited on the second dielectric layer 23. Then, a dry etching process is performed with respect to the second dielectric layer 23, so that a trench 25 is formed in the second dielectric layer 23. Simultaneously with the trench etching (i.e., in the same etch process chamber, without breaking vacuum therein), via holes 26 are formed in the first interlayer dielectric layer 22. Although the via holes are etched in the same etch process step as the trench, one or more changes to the etch chemistry can be made during the “one-step” etch process. At this time, the etch stop layer 30 may serve as an etch mask.

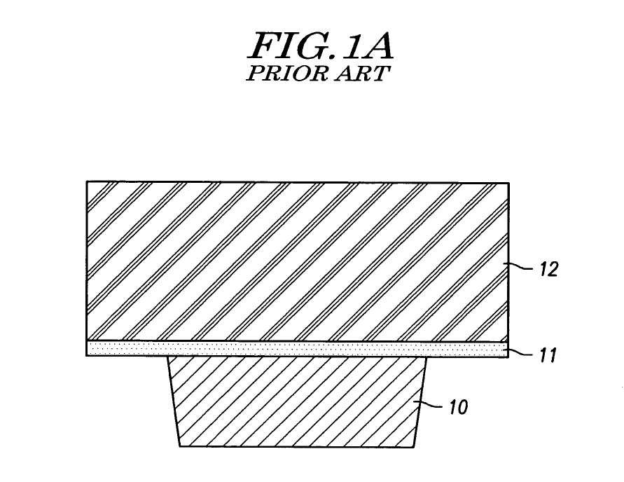

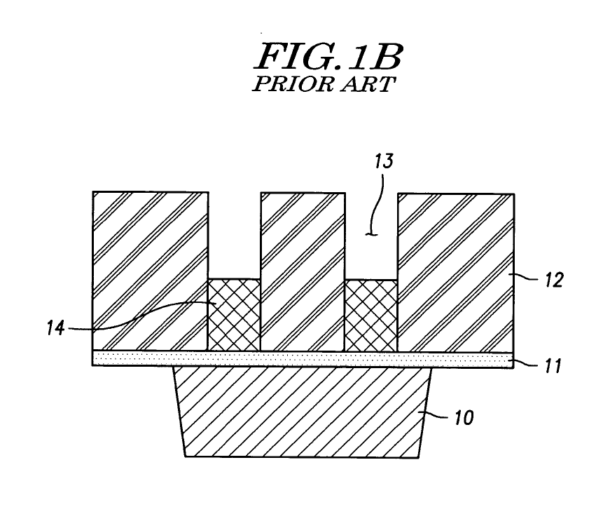

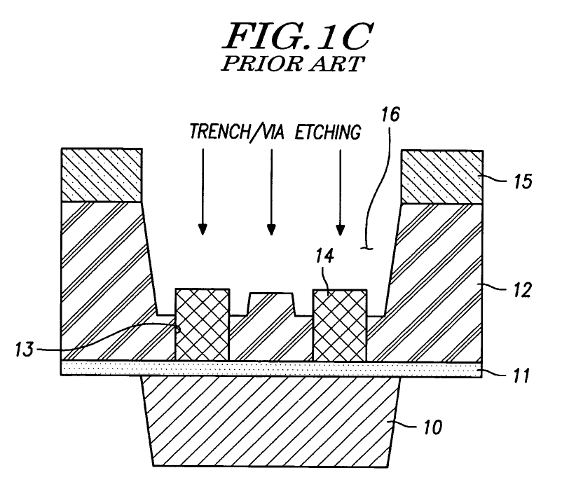

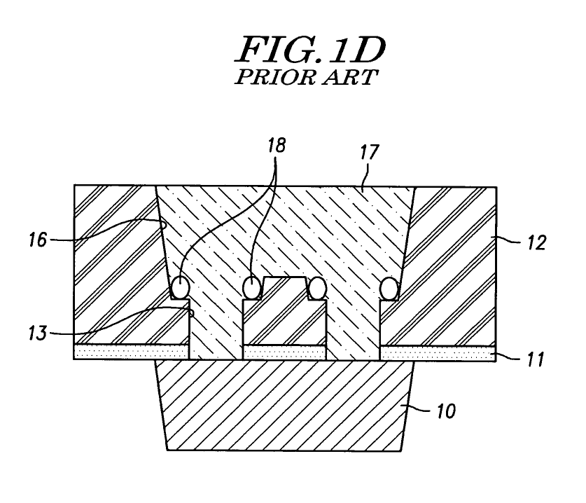

In this manner, the trench 25 and the via holes 26 can be simultaneously formed using the buried etch stop layer 30. Accordingly, the depth of the trench can be precisely controlled so that it is possible to optimize the sheet resistance and to prevent or reduce copper voids caused by an overlap between the trench and the via hole. In addition, different from the conventional dual damascene process in which the via holes are formed separately from the trench so that the protective layer 14 (see, FIG. 1c) becomes advantageous for protecting the via holes during the trench etching process, the present invention does not require a protective layer because the via holes and the trench are simultaneously formed in a single photolithographic step (e.g., patterning and etching sequence).

After simultaneously forming the trench and via holes, as shown in FIG. 2d, the capping layer 21 exposed at the bottom of the via holes 26 is removed. The capping layer 21 may comprise silicon nitride (SiN) or silicon carbon nitride (SiCN), for example. Then, although it is not shown in figures, an anti-diffusion layer and a copper seed layer (e.g., Cu, Ti, Ta, Hf, or Ru, typically formed by chemical vapor deposition or atomic layer deposition, and which may have a thin electroplated film of the same metal thereon as an additional seed layer if the initial seed layer is not Cu) are deposited, and then copper is deposited through an electrochemical plating process such that the via holes 26 and the trench 25 are filled with copper. After that, chemical mechanical polishing is performed, thereby obtaining a copper interconnection 27 having the dual damascene structure. The anti-diffusion layer, for example, includes a tantalum-based metal or a titanium-based metal (e.g., TiN or TaN, which may have an adhesive layer such as Ti or Ta thereunder). In addition, a heat-treatment process may be performed after or before the chemical mechanical polishing process.

As described above, according to the method of forming the copper interconnection of the present invention, a patterned etch stop layer is formed between (interlayer) dielectric layers, and the trench and the via holes are simultaneously formed by etching using the buried etch stop layer as a via hole mask.

Thus, the method of the present invention can precisely control the depth of the trench using the etch stop layer, so that the sheet resistance can be optimized. In addition, since the via holes and the trench are etched simultaneously using the etch stop layer, it is not necessary to separately form the via holes and/or to provide the protective layer that protects the via holes, so that the manufacturing processes can be simplified and the manufacturing cost can be reduced. Furthermore, the copper voids caused by an overlap between the trench and the via holes can be reduced or prevented, and the etch profile anomaly caused by the trench etching process can be improved. In addition, the reliability of the semiconductor device, such as electro-migration or stress-migration, can be improved.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method of forming a copper interconnection, the method comprising the steps of:
sequentially depositing a capping layer and a first dielectric layer on a lower structure;
depositing an etch stop layer on the first dielectric layer;
etching the etch stop layer to form a via hole pattern therein;
depositing a second dielectric layer on the etch stop layer and the first dielectric layer;
forming a photoresist pattern on the second interlayer dielectric layer;
etching the second dielectric layer using the photoresist pattern as a mask, thereby forming the trench, and simultaneously etching the first dielectric layer through the buried etch stop layer, thereby forming via holes;
removing the capping layer exposed in the via holes; and
depositing copper such that the via holes and the trench are filled with copper, and chemical mechanical polishing a resultant structure, thereby obtaining the copper interconnection.

2. The method of claim 1, wherein the etch stop layer includes a material having an etching selectivity in a range of 10:1 to 100:1 with respect to the first dielectric layer.

3. The method of claim 1, wherein the etch stop layer comprises silicon nitride (SiN).

4. The method of claim 1, wherein a deposition thickness of the first dielectric layer corresponds to a depth of the via hole.

5. The method of claim 1, wherein the first dielectric layer includes a material identical to a material in the second interlayer dielectric layer.

6. The method of claim 1, wherein the first and second dielectric layers include fluorine-doped silicon glass (FSG) or carbon-doped silicon oxide (SiOC).

7. The method of claim 6, further comprising forming a first undoped silicate glass (USG) layer on the capping layer before forming the first dielectric layer, and forming a second undoped silicate glass (USG) layer after forming the first dielectric layer and before forming the etch stop layer.

8. The method of claim 6, wherein the first and second dielectric layers comprise carbon-doped silicon oxide (SiOC).

9. The method of claim 1, wherein the capping layer comprises silicon nitride (SiN) or silicon carbon nitride (SiCN).

10. The method of claim 1, wherein the capping layer comprises silicon carbon nitride (SiCN).

11. A semiconductor device comprising;
a capping layer and a first dielectric layer, in sequence on a top surface of a lower structure;
an etch stop layer on a top surface of the first dielectric layer;
a plurality of via holes formed through the capping layer, the first dielectric layer and the etch stop layer;
a second dielectric layer on the etch stop layer having a trench therein over the via holes; and
a copper interconnection in the via holes and the trench.

12. The semiconductor device of claim 11, wherein the etch stop layer includes a material having an etching selectivity in a range of 10:1 to 100:1 with respect to the first dielectric layer.

13. The semiconductor device of claim 11, wherein the etch stop layer comprises silicon nitride (SiN).

14. The semiconductor device of claim 11, wherein the etch stop layer has a thickness of 500 Å˜700 Å.

15. The semiconductor device of claim 11, wherein a deposition thickness of the first dielectric layer corresponds to a depth of the via hole.

16. The semiconductor device of claim 11, wherein the first and second dielectric layers include fluorine-doped silicon glass (FSG) or carbon-doped silicon oxide (SiOC).

17. The semiconductor device of claim 16, wherein the first and second dielectric layers comprise carbon-doped silicon oxide (SiOC).

18. The semiconductor device of claim 16, further comprising a first undoped silicate glass (USG) layer between the capping layer and the first dielectric layer, and a second undoped silicate glass (USG) layer between the first dielectric layer and the etch stop layer.

19. The semiconductor device of claim 11, wherein the capping layer comprises silicon nitride (SiN) or silicon carbon nitride (SiCN).

20. The semiconductor device of claim 10, wherein the capping layer comprises silicon carbon nitride (SiCN).
